(19) United States
(12) Patent Application Publication
(10) Pub. No.: US 2025/0131137 A1
(43) Pub. Date: Apr. 24, 2025

(54) OFFSHORE WIND POWER-BASED WATER ELECTROLYSIS SYSTEM AND METHOD FOR MAINTAINING AND MANAGING THE SAME

(71) Applicant: INDUSTRY-ACADEMIC COOPERATION FOUNDATION, KUNSAN NATIONAL UNIVERSITY, Jeollabuk-do (KR)

(72) Inventors: Ki-Weon KANG, Gyeonggi-do (KR); Yun-Jung JANG, Jeollabuk-do (KR); Hak-Geun KIM, Jeollabuk-do (KR); Byung-Wook JEON, Jeollabuk-do (KR)

(21) Appl. No.: 18/663,475

(22) Filed: May 14, 2024

(30) Foreign Application Priority Data
Oct. 24, 2023 (KR) 10-2023-0142589

(51) Int. Cl. G06F 30/12; F03D 9/19; F03D 17/00

(52) U.S. Cl. CPC G06F 30/12; F03D 9/19; F03D 17/006; F05B 2220/61

(57) ABSTRACT

An offshore wind power-based water electrolysis system includes an offshore wind turbine generator installed offshore to produce electricity using offshore wind energy, a water electrolysis facility installed offshore to produce hydrogen by electrolysis of water using the electricity, a hydrogen maritime transport apparatus to transport the hydrogen produced through the water electrolysis facility to onshore, a hydrogen above-ground storage facility installed on ground to store the transported hydrogen and dispense the hydrogen to ground transport apparatuses, and a system maintenance and management apparatus to calculate and notify a remaining useful life of blades in the offshore wind turbine generator by performing debonding damage simulation, fatigue crack growth simulation and remaining useful life simulation of the blades in a sequential order, and determine and notify stability through finite element analysis for each hydrogen tank in the hydrogen maritime transport apparatus and the hydrogen above-ground storage facility.

### CROSS REFERENCE TO RELATED APPLICATION AND CLAIM OF PRIORITY

This application claims the benefit under 35 USC § 119 of Korean Patent Applications No. 10-2023-0142589, filed on Oct. 24, 2023, in the Korean Intellectual Property Office, the entire disclosure of which is incorporated herein by reference for all purposes.

### BACKGROUND

### 1. Technical Field

The present disclosure relates to a water electrolysis system for producing hydrogen fuel through offshore wind turbine generation and storing and transporting the hydrogen fuel, and more particularly, to a hydrogen fuel production and transport system for determining and monitoring the remaining useful life of an offshore wind turbine generator-based water electrolysis system and a method for maintaining and managing the same.

### 2. Background Art

Water electrolysis is technology that produces hydrogen by electrolysis of water using renewable energy output such as wind energy and solar energy as shown in FIG. 1, or converts the produced hydrogen to methane by reaction with carbon dioxide and stores and utilizes the same.

A water electrolysis system includes a power generation facility to generate renewable energy, a water electrolysis facility to produce hydrogen by electrolysis of water through electricity, a methanation facility, a hydrogen and methane storage facility and an electricity and gas grid connected facility, and the produced hydrogen and methane are used as a fuel for power generation in fuel batteries or gas turbines or a transport fuel in hydrogen cars.

However, there is no technology to predict and monitor the remaining useful life of an offshore wind turbine generator and stability of a hydrogen tank, causing the operators' inconvenience of having to observe the offshore wind turbine generator and the hydrogen tank with their eyes to check the current condition.

### SUMMARY

To solve the above-described problem, the present disclosure is directed to providing an offshore wind power-based water electrolysis system for determining and monitoring the remaining useful life of an offshore wind power-based water electrolysis system and a method for maintaining and managing the same.

The objectives of the present disclosure are not limited to the above-mentioned objectives and these and other objectives will be clearly understood by persons having ordinary skill in the technical field pertaining to the present disclosure from the following description.

To solve the above-described problem, according to an embodiment of the present disclosure, there is provided an offshore wind power-based water electrolysis system including an offshore wind turbine generator installed offshore to produce electricity using offshore wind energy; a water electrolysis facility installed offshore to produce hydrogen by electrolysis of water using the electricity; a hydrogen maritime transport apparatus to transport the hydrogen produced through the water electrolysis facility to onshore; a hydrogen above-ground storage facility installed on ground to store the transported hydrogen and dispense the hydrogen to ground transport apparatuses; and a system maintenance and management apparatus to calculate and notify a remaining useful life of blades in the offshore wind turbine generator by performing debonding damage simulation, fatigue crack growth simulation and remaining useful life simulation of the blades in a sequential order, and determine and notify stability through finite element analysis for each hydrogen tank in the hydrogen maritime transport apparatus and the hydrogen above-ground storage facility.

The system maintenance and management apparatus includes a design stage simulation unit configured to calculate a predicted crack growth for each crack initiation location and load by performing the debonding damage simulation of the blades; and

an operation stage simulation unit configured to acquire a predicted crack propagation length for each turbulence model load by performing the fatigue crack propagation simulation, and acquire a predicted remaining useful life of the blades by performing the remaining useful life simulation reflecting the predicted crack propagation length for each turbulence model load and the predicted crack growth for each crack initiation location and load.

The design stage simulation unit is configured to perform at least one of the debonding damage simulation and the fatigue crack propagation simulation, and the debonding damage simulation reconstructs a 3-dimensional blade model with at least one input of blade model type, material properties, bonding condition, fracture toughness and bond thickness and interface characteristics, and predicts the crack growth for each crack initiation location and load through an interfacial fracture toughness based analytic modeling technique.

The operation stage simulation unit is configured to perform the fatigue crack growth simulation to predict fatigue crack propagation characteristics with at least one input of fatigue crack propagation characteristics and physical numerical analysis condition, fatigue load data and waveform, constant and turbulence model load blocks, final numerical analysis and repeated recovery value, and perform the remaining useful life simulation to analyze buckling characteristics for each blade model based on the debonding damage simulation results and the fatigue crack growth simulation results, and predict the remaining useful life based on the buckling characteristics for each blade model.

The system maintenance and management apparatus includes a hydrogen tank modeling unit configured to generate a finite element model by defining Computer Aided Design (CAD) geometry and mesh of the hydrogen tank including a boss part used to fill the hydrogen tank; and a structural analysis unit configured to determine material properties, laminate structure, boundary condition, load condition and bonding condition for evaluating structural stability through the finite element model, and evaluate structural safety of the hydrogen tank using the finite element model.

The structural analysis unit is configured to evaluate structural safety of the hydrogen tank through methodology of failure evaluation criteria based on at least one of limit criteria, interactive criteria and separate mode criteria.

The structural analysis unit is further configured to re-design the boss part when an operating pressure criterion of the hydrogen tank is met but integrity of the boss part is not ensured, and perform a structural safety evaluation operation of the hydrogen tank when the operating pressure criterion is met and structural integrity of the boss part is ensured at a same time.

The present disclosure may predict the remaining useful life of the offshore wind turbine generator by performing bonding damage simulation, fatigue crack growth simulation and remaining useful life simulation of the blades in a sequential order, and determine and monitor the remaining useful life of the offshore wind turbine generator and safety of the hydrogen tank in the water electrolysis system more easily through the system maintenance and management apparatus.

### BRIEF DESCRIPTION OF THE DRAWINGS

FIG. 1 is a diagram showing a commonly used water electrolysis system.

FIG. 2 is a diagram illustrating an offshore wind power-based water electrolysis system according to an embodiment of the present disclosure.

FIGS. 3 to 5 are diagrams illustrating a system maintenance and management apparatus according to an embodiment of the present disclosure.

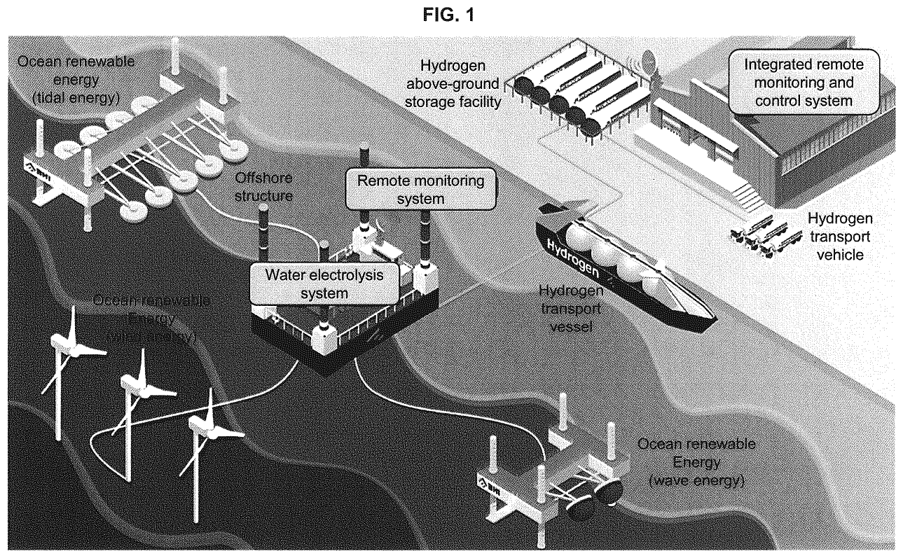

### DETAILED DESCRIPTION

Hereinafter, exemplary embodiments of the present disclosure will be described in sufficient detail with reference to the accompanying drawings to enable persons having ordinary skill in the technical field pertaining to the present disclosure to easily carry out the present disclosure. However, in describing the exemplary embodiments of the present disclosure, when it is determined that a certain detailed description of relevant known functions or elements may unnecessarily obscure the subject matter of the present disclosure, the detailed description is omitted. Throughout the accompanying drawings, elements having similar functions and operations are given the same reference numerals.

In addition, it should be understood that when an element is referred to as being ‘connected to’ another element, it can be directly connected to the other element or intervening elements may be present. Furthermore, the term ‘comprises’ specifies the presence of stated elements, but does not preclude the presence or addition of one or more other elements unless the context clearly indicates otherwise.

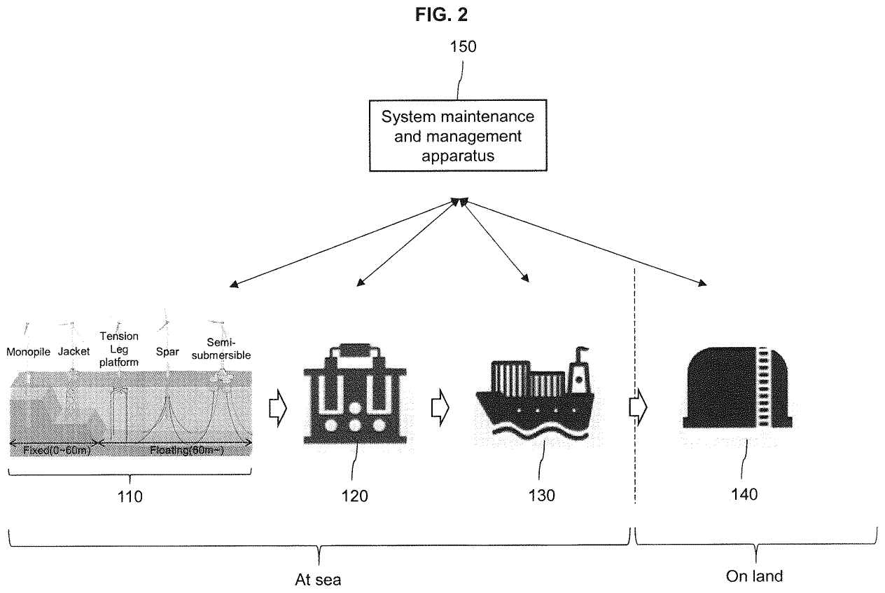

FIG. 2 is a diagram illustrating an offshore wind power-based water electrolysis system according to an embodiment of the present disclosure.

Referring to FIG. 2, the system of the present disclosure includes an offshore wind turbine generator 110, a water electrolysis facility 120, a hydrogen maritime transport apparatus 130, a hydrogen above-ground storage facility 140 and a system maintenance and management apparatus 150.

The offshore wind turbine generator 110 is installed offshore to produce electricity using offshore wind energy.

The offshore wind turbine generator 110 of the present disclosure may change in blade support structure depending on the depth of water and the soil condition, and in this instance, the type of support structure may include monopile, jacket, tension leg platform, spar and semi-submersible, but is not limited thereto.

The water electrolysis facility 120 is installed offshore to produce hydrogen by electrolysis of water using electricity.

The hydrogen maritime transport apparatus 130 is a hydrogen transport vessel equipped with hydrogen tanks and transports the hydrogen produced through the water electrolysis facility 120 to onshore.

The hydrogen above-ground storage facility 140 includes a plurality of hydrogen tanks installed on the ground, and stores the hydrogen transported by the hydrogen maritime transport apparatus 130 in the hydrogen tanks and dispenses the hydrogen to vehicles for transporting hydrogen under the control of an operator.

The system maintenance and management apparatus 150 remotely controls and monitors the overall operation of the water electrolysis system.

In addition to this, the system maintenance and management apparatus 150 of the present disclosure calculates and notifies the remaining useful life (RUL) of blades in the offshore wind turbine generator 110 by performing debonding damage simulation, fatigue crack growth simulation and remaining useful life simulation of the blades.

Furthermore, the system maintenance and management apparatus 150 determines and notifies stability through finite element analysis for each hydrogen tank in the hydrogen maritime transport apparatus 130 and the hydrogen above-ground storage facility 140.

That is, the present disclosure includes the system maintenance and management apparatus 150 with which it is possible to determine and monitor the remaining useful life of the offshore wind turbine generator and stability of the hydrogen tank in the water electrolysis system more easily.

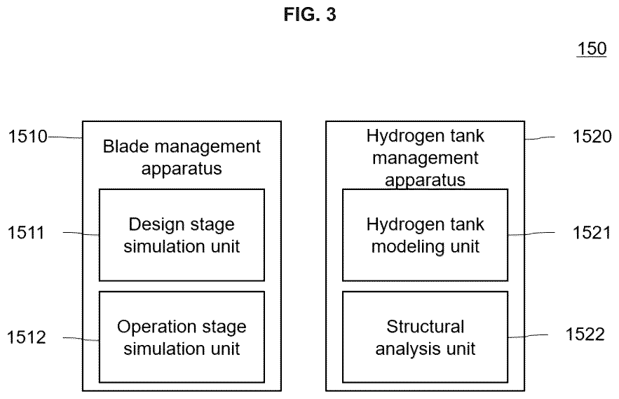

FIG. 3 is a diagram illustrating the system maintenance and management apparatus according to an embodiment of the present disclosure.

As shown in FIG. 3, the system maintenance and management apparatus 150 of the present disclosure includes a blade management apparatus 1510 and a hydrogen tank management apparatus 1520.

First, the blade management apparatus 1510 includes a design stage simulation unit 1511 and an operation stage simulation unit 1512.

The design stage simulation unit 1511 performs debonding damage simulation.

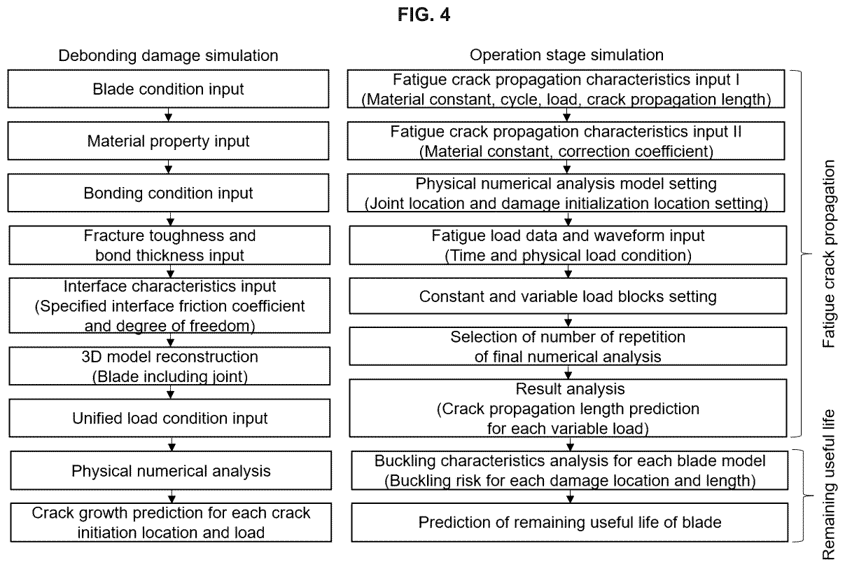

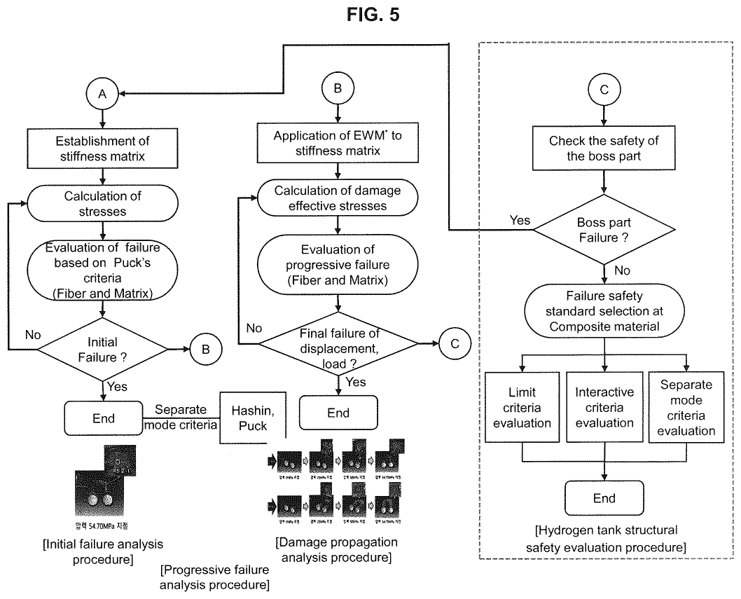

As shown in FIG. 4, the debonding damage simulation reconstructs a 3-dimensional blade model based on at least one input of blade model type, material properties, bonding condition (for example, delamination, debonding), inter lamina fracture and bond thickness, interface characteristics (for example, specified interface friction coefficient and degree of freedom), and predicts crack initiation and growth locations at spar cap-shear web and trailing edge joints under extreme loading for each blade by using an interfacial fracture toughness based analytic modeling technique (Cohesive Zone Modeling (CZM)).

As shown in FIG. 4, the operation stage simulation unit 1512 performs operation stage simulation to calculate the remaining useful life of the blade by performing fatigue crack growth simulation and remaining useful life simulation in a sequential order.

The fatigue crack growth simulation predicts fatigue crack propagation characteristics (for example, crack propagation length for each turbulence model load) based on at least one input of fatigue crack propagation characteristics (for example, material constant, cycle, load, crack propagation length, material constant, correction coefficient), physical numerical analysis condition (for example, joint location, damage initiation location setting), fatigue load data and waveform (for example, time and physical load condition), constant and turbulence model load blocks, final numerical analysis and repeated recovery value.

In this instance, fatigue crack propagation characteristics analysis is performed by analyzing the crack propagation life of the trailing edge (TE) and the spar cap-shear web joint for each blade under fatigue loading by analysis using extended Finite Element Method (XFEM) based adhesive damage modeling technique (Virtual Crack Closure Technique (VCCT)) and comparative analysis of test results, and as a result, constant amplitude load (calculation through GH-Bladed) and turbulence model load (variation in rated wind speed) are calculated.

The remaining useful life simulation analyzes buckling characteristics (for example, buckling risk for each damage location and length) for each blade model based on the debonding damage simulation results (for example, predicted crack growth for each crack initiation location and load) and the fatigue crack growth simulation results (for example, predicted crack propagation length for each turbulence model load), and predicts the remaining useful life based on the buckling characteristics for each blade model.

The hydrogen tank management apparatus 1520 includes a hydrogen tank modeling unit 1521 and a structural analysis unit 1522.

The hydrogen tank modeling unit 1521 generates a finite element model by defining Computer Aided Design (CAD) geometry and mesh of the hydrogen tank including a boss part used to fill the hydrogen tank.

The structural analysis unit 1522 determines material properties, laminate structure, boundary condition, load condition and bonding condition for evaluating structural stability using the finite element model through an algorithm shown in FIG. 4, and evaluates structural safety of the hydrogen tank using the finite element model.

Furthermore, the structural analysis unit 1522 determines whether to perform the structural safety evaluation operation by double-checking the operating pressure criterion of the hydrogen tank and stability of the boss part.

That is, even though the hydrogen tank meets the operating pressure criterion, unless integrity of the boss part is first ensured under the operating pressure, the structural analysis unit 1522 determines that structural safety is not ensured, and requires re-design of the boss part. Additionally, when the operating pressure criterion is met and structural integrity of the boss part is ensured at the same time, the structural analysis unit 1522 may evaluate structural safety of the hydrogen tank through methodology of failure evaluation criteria based on at least one of limit criteria, interactive criteria and separate mode criteria of the hydrogen tank. As a result, it may be possible to evaluate structural safety by applying suitable evaluation criteria for a variety of conditions such as a variety of environments, structures, etc.

Although the exemplary embodiments of the present disclosure have been hereinabove illustrated and described, the present disclosure is not limited to the above-described particular embodiments, and it is obvious that variations may be made to the embodiments by persons having ordinary skill in the technical field pertaining to the present disclosure without departing from the claimed subject matter of the present disclosure, and such variations should not be understood apart from the technical spirit or scope of the present disclosure.

What is claimed is:

1. An offshore wind power-based water electrolysis system comprising:
an offshore wind turbine generator configured to be installed offshore to produce electricity using offshore wind energy;
a water electrolysis facility configured to be installed offshore to produce hydrogen by electrolysis of water using the electricity;
a hydrogen maritime transport apparatus configured to transport the hydrogen produced through the water electrolysis facility to onshore;
a hydrogen above-ground storage facility configured to be installed on ground to store the transported hydrogen and dispense the hydrogen to ground transport apparatuses; and
a system maintenance and management apparatus configured to calculate and notify a remaining useful life of blades in the offshore wind turbine generator by performing debonding damage simulation, fatigue crack growth simulation and remaining useful life simulation of the blades in a sequential order, and determine and notify stability through finite element analysis for each hydrogen tank in the hydrogen maritime transport apparatus and the hydrogen above-ground storage facility.

2. The offshore wind power-based water electrolysis system according to claim 1, wherein the system maintenance and management apparatus includes:
a design stage simulation unit configured to calculate a predicted crack growth for each crack initiation location and load by performing the debonding damage simulation of the blades; and
an operation stage simulation unit configured to acquire a predicted crack propagation length for each turbulence model load by performing the fatigue crack propagation simulation, and acquire a predicted remaining useful life of the blades by performing the remaining useful life simulation reflecting the predicted crack propagation length for each turbulence model load and the predicted crack growth for each crack initiation location and load.

3. The offshore wind power-based water electrolysis system according to claim 2, wherein the design stage simulation unit is configured to perform at least one of the debonding damage simulation and the fatigue crack propagation simulation, and
wherein the debonding damage simulation reconstructs a 3-dimensional blade model with at least one input of blade model type, material properties, bonding condition, fracture toughness and bond thickness and interface characteristics, and predicts the crack growth for each crack initiation location and load through an interfacial fracture toughness based analytic modeling technique.

4. The offshore wind power-based water electrolysis system according to claim 2, wherein the operation stage simulation unit is configured to perform:
the fatigue crack growth simulation to predict fatigue crack propagation characteristics with at least one input of fatigue crack propagation characteristics and physical numerical analysis condition, fatigue load data and waveform, constant and turbulence model load blocks, final numerical analysis and repeated recovery value, and
the remaining useful life simulation to analyze buckling characteristics for each blade model based on the debonding damage simulation results and the fatigue crack growth simulation results, and predict the remaining useful life based on the buckling characteristics for each blade model.

5. The offshore wind power-based water electrolysis system according to claim 1, wherein the system maintenance and management apparatus includes:
a hydrogen tank modeling unit configured to generate a finite element model by defining Computer Aided Design (CAD) geometry and mesh of the hydrogen tank including a boss part used to fill the hydrogen tank; and
a structural analysis unit configured to determine material properties, laminate structure, boundary condition, load condition and bonding condition for evaluating structural stability through the finite element model, and evaluate structural safety of the hydrogen tank using the finite element model.

6. The offshore wind power-based water electrolysis system according to claim 5, wherein the structural analysis unit is configured to re-design the boss part when an operating pressure criterion of the hydrogen tank is met but integrity of the boss part is not ensured, and perform a structural safety evaluation operation of the hydrogen tank when the operating pressure criterion is met and structural integrity of the boss part is ensured at a same time.
